(19) United States
(12) Patent Application Publication
(10) Pub. No.: US 2024/0069431 A1
(43) Pub. Date: Feb. 29, 2024

(54) METHOD OF MANUFACTURING PHOTO MASKS

(71) Applicant: TAIWAN SEMICONDUCTOR MANUFACTURING COMPANY, LTD., Hsinchu (TW)

(72) Inventors: Wei-Che HSIEH, Taipei (TW); Chien-Cheng Chen, Hsinchu (TW); Ping-Hsun Lin, New Taipei City (TW); Ta-Cheng Lien, Hsinchu County (TW); Hsin-Chang Lee, Hsinchu County (TW)

(21) Appl. No.: 18/110,838

(22) Filed: Feb. 16, 2023

Related U.S. Application Data
(60) Provisional application No. 63/402,853, filed on Aug. 31, 2022.

(51) Int. Cl. G03F 1/32

(52) U.S. Cl. CPC G03F 1/32

(57) ABSTRACT

In a method of manufacturing an attenuated phase shift mask, a photo resist pattern is formed over a mask blank. The mask blank includes a transparent substrate, an etch stop layer on the transparent substrate, a phase shift material layer on the etch stop layer, a hard mask layer on the phase shift material layer and an intermediate layer on the hard mask layer. The intermediate layer is patterned by using the photo resist pattern as an etching mask, the hard mask layer is patterned by using the patterned intermediate layer as an etching mask, and the phase shift material layer is patterned by using the patterned hard mask layer as an etching mask. The intermediate layer includes at least one of a transition metal, a transition metal alloy, or a silicon containing material, and the hard mask layer is made of a different material than the intermediate layer.

### PRIORITY CLAIM AND CROSS-REFERENCE

This application claims the benefit of U.S. Provisional Patent Application No. 63/402,853, filed Aug. 31, 2022, the entire content of which is incorporated herein by reference.

### BACKGROUND

The semiconductor industry has experienced exponential growth. Technological advances in materials and design have produced generations of integrated circuits (ICs), where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C and 1D show cross sectional views of photo masks according to embodiments of the present disclosure.

FIGS. 2A, 2B, 2C, 2D, 2E, 2F, 2G, 2H and 2I show cross-sectional views of various stages of a sequential manufacturing operation of a photo mask in accordance with embodiments of the present disclosure.

FIGS. 3A, 3B, 3C, 3D, 3E and 3F show cross-sectional views of various stages of a sequential manufacturing operation of a photo mask in accordance with embodiments of the present disclosure.

FIGS. 4A, 4B, 4C, 4D, and 4E show cross-sectional views of various stages of a sequential manufacturing operation of a photo mask in accordance with embodiments of the present disclosure.

FIGS. 5A, 5B, 5C, 5D, 5E and 5F show cross-sectional views of various stages of a sequential manufacturing operation of a photo mask in accordance with embodiments of the present disclosure.

FIGS. 6A, 6B, 6C and 6D show cross sectional views of photo mask blanks according to embodiments of the present disclosure.

FIG. 7A shows a flowchart of a method making a semiconductor device, and FIGS. 7B, 7C, 7D and 7E show a sequential manufacturing operation of a method of making a semiconductor device in accordance with embodiments of present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the manufacture of integrated circuits (ICs), patterns representing different layers of the ICs are fabricated using a series of reusable photomasks (also referred to herein as photolithography masks or masks). The photomasks are used to transfer the design of each layer of the ICs onto a semiconductor substrate during the semiconductor device fabrication process.

With the shrinkage in IC size, various types of this lithography techniques such as immersion lithography utilizing wavelengths on the order of 193 nm from an ArF laser or extreme ultraviolet (EUV) light with a wavelength of 13.5 nm are employed in, for example, a lithographic process to enable transfer of very small patterns (e.g., nanometer-scale patterns) from a mask to a semiconductor wafer.

An ongoing desire to have more densely packed integrated devices has resulted in changes to the photolithography process in order to form smaller individual feature sizes. The minimum feature size or “critical dimension” (CD) obtainable by a process is determined approximately by the formula CD=k₁*λ/NA, where k₁ is a process-specific coefficient, λ is the wavelength of applied light/energy, and NA is the numerical aperture of the optical lens as seen from the substrate or wafer.

For fabrication of dense features with a given value of k₁, the ability to project a usable image of a small feature onto a wafer is limited by the wavelength λ and the ability of the projection optics to capture enough diffraction orders from an illuminated mask. When either dense features or isolated features are made from a photomask or a reticle of a certain size and/or shape, the transitions between light and dark at the edges of the projected image may not be sufficiently sharply defined to correctly form target photoresist patterns. This may result, among other things, in reducing the contrast of aerial images and also the quality of resulting photoresist profiles. As a result, features 150 nm or below in size may need to utilize phase shifting masks (PSMs) or techniques to enhance the image quality at the wafer, e.g., sharpening edges of features to improve resist profiles.

Phase-shifting generally involves selectively changing phases of part of the energy passing through a photomask/reticle so that the phase-shifted energy is additive or subtractive with energy that is not phase-shifted at the surface of the material on the wafer that is to be exposed and patterned. By carefully controlling the shape, location, and phase shift angle of mask features, the resulting photoresist patterns can have more precisely defined edges. As the feature size is reduced, an imbalance of transmission intensity between the 0° and 180° phase portions and a phase shift that varies from 180° can result in significant critical dimension (CD) variation and placement errors for the photoresist pattern.

Phase shifts may be obtained in a number of ways. For example, one process known as attenuated phase shifting mask (APSM) includes a layer of non-opaque material that causes light passing through the non-opaque material to change in phase compared to light passing through transparent parts of the mask. In addition, the non-opaque material can adjust the amount (intensity/magnitude) of light transmitted through the non-opaque material compared to the amount of light transmitted through transparent portions of the mask.

The phase shifting material is a material that affects the phase of the light passing through the phase shifting material such that the phase of the light passing through the phase shifting material is shifted relative to the phase of the light that does not pass through the phase shifting material, e.g., passes only through the transparent mask substrate material without passing through the phase shifting material. The phase shifting material can also reduce the amount of light transmitted through the phase shifting material relative to the amount of incident light that passes through portions of the mask not covered by the phase shifting material.

During formation of the patterned phase shifting material, a photo resist pattern is formed over a hard mask layer which is formed over the phase shifting material layer. As the pattern size decreases, suppressing resist pattern collapse and corner rounding of hard mask patterns have become more important, along with obtaining an APSM to produce the desired phase shift.

In embodiments of the present disclosure, multilayer resist systems with or without a combination of multiple hard mask layers in a patterning operation are disclosed.

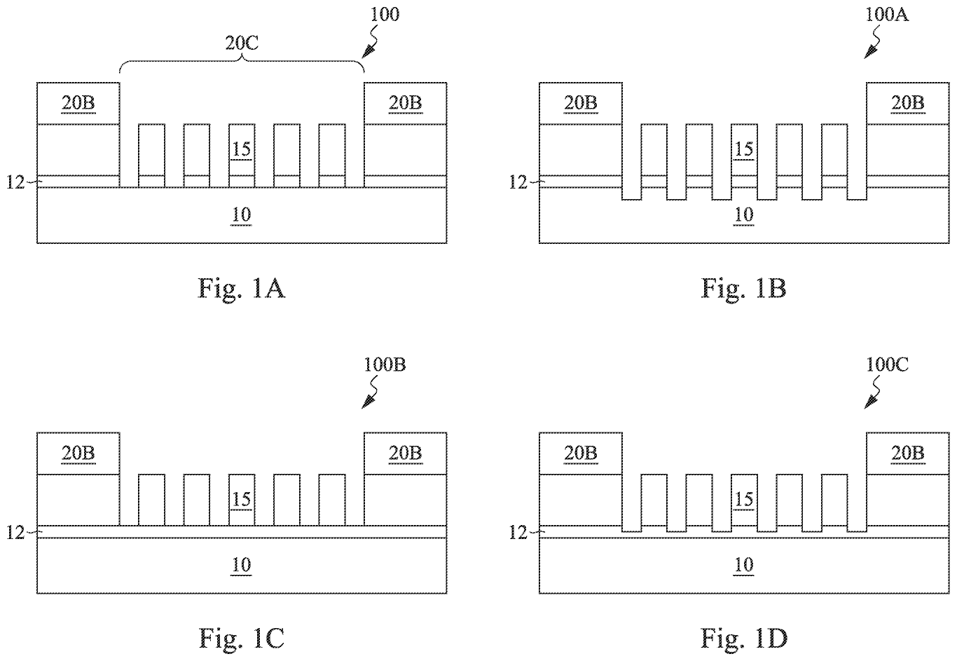

FIG. 1A is a cross-sectional view of a photo mask 100, e.g., an APSM, in accordance with an embodiment of the present disclosure. Referring to FIG. 1A, the APSM 100 includes a substrate 10 and a phase shift layer 15 over a front surface of the substrate 10. Between the phase shift layer 15 and substrate 10 is an etch stop layer 12. In the embodiment illustrated in FIG. 1A, portions of phase shift layer 15 and etch stop layer 12 are removed to provide openings, through which the upper surface of substrate 10 is exposed. In the embodiment of FIG. 1A, a transparency to light (e.g., ArF laser or KrF laser light) is less than 100% and in a range from about 95% to 99.5%. The ASPM 100 includes image border features 20B around a periphery of an image region (circuit pattern region) 20C of the ASPM 100. In some embodiments, the phase shift material layer 15 and the etch stop layer 12 are etched such that portions of the phase shift material layer 12 and the etch stop layer 12 underlying the image border features 20B are separated from the balance of the phase shift material layer 15 and etch stop layer 12. In such embodiments, the portions of the phase shift material layer 15 and the etch stop layer 12 underlying the image border feature 20B are separated from the balance of the phase shift material layer 15 and the etch stop layer 12 by a trench (not shown).

FIG. 1B is a cross-sectional view of an APSM 100A, in accordance with another embodiment of the present disclosure. Referring to FIG. 1B, in the APSM 100A, the portions of the substrate 10 exposed in the openings are etched or recessed. The recessed amount is adjusted such that the phase difference between the light passing through the phase shift layer 15 and the etch stop layer 12 and the light that does not pass therethrough has a desired phase shift amount.

FIG. 1C is a cross-sectional view of an APSM 100B, in accordance with another embodiment of the present disclosure. In the APSM 100B of FIG. 1C, the etch stop layer 12 is not removed at the bottom of the openings.

FIG. 1D is a cross-sectional view of an APSM 100C, in accordance with another embodiment of the present disclosure. In the APSM 100C of FIG. 1D, the etch stop layer 12 is partially removed at the bottom of the openings.

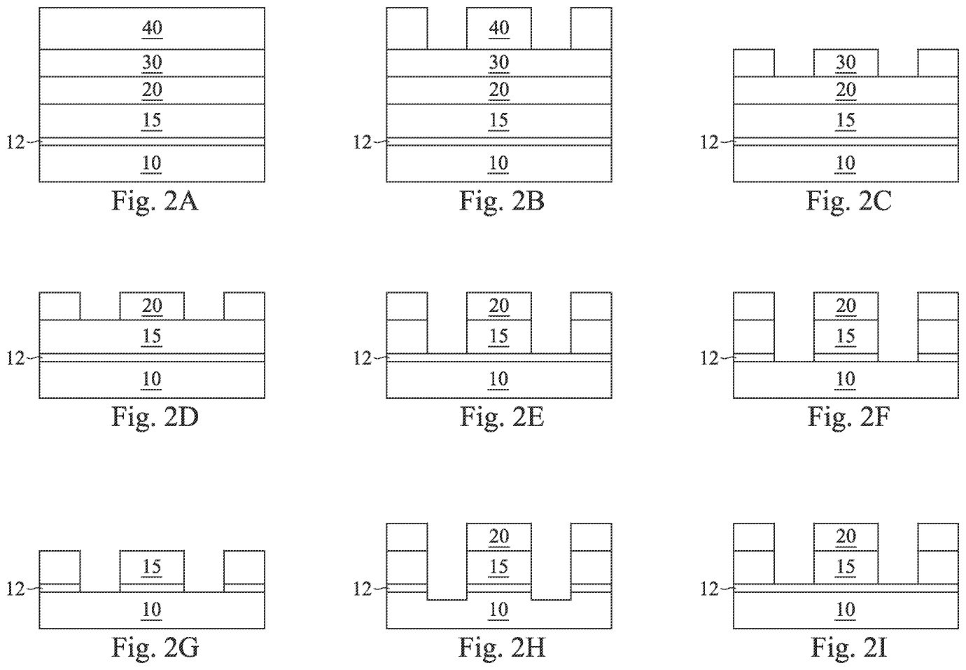

FIGS. 2A through 2I are cross-sectional views of various stages of a sequential fabrication process of an APSM, in accordance with some embodiments. In some embodiments, additional operations are performed before, during, and/or after the process of FIGS. 2A-2I, or some of the operations described are replaced and/or eliminated. In some embodiments, some of the features described below are replaced or eliminated. One of ordinary skill in the art would understand that although some embodiments are discussed with operations performed in a particular order, these operations may be performed in another logical order.

Referring to FIG. 2A, an etch stop layer 12, a phase shift material layer 15 and a hard mask layer 20 are disposed over a substrate 10, as a mask blank (no circuit pattern has been formed) in accordance with some embodiments. In some embodiments, a multilayer resist system including an intermediate layer 30 and a photo resist layer 40 is formed over the hard mask layer 20 as shown in FIG. 2A.

The substrate 10 is made of glass, silicon, quartz or other low thermal expansion materials in some embodiments. The low thermal expansion material helps to minimize image distortion due to mask heating during use of the photo mask. In some embodiments, the substrate 10 includes fused silica, fused quartz, calcium fluoride, silicon carbide, black diamond, or titanium oxide doped silicon oxide (SiO₂/TiO₂). In some embodiments, the substrate 10 has a thickness ranging from about 1 mm to about 7 mm. If the thickness of the substrate 10 is too small, a risk of breakage or warping of the photo mask increases, in some instances. On the other hand, if the thickness of the substrate 10 is too great, a weight and cost of the photo mask is needlessly increased, in some instances.

In some embodiments, the etch stop layer 12 is in direct contact with the front surface of the substrate 10. In some embodiments, the etch stop layer 12 is transmissive or semi-transmissive to light energy used in photolithography processes. For example, in some embodiments, the etch stop layer is transmissive or semi-transmissive to deep UV or near UV light energy used in immersion lithography. In some embodiments, the exposure radiation is light from an ArF excimer laser having a wavelength of about 193 nm or a KrF excimer laser having wavelength of about 254 nm. Semi-transmissive to light or radiation means that a material transmits less than 70% of light that is incident on a surface of the material, and the transmissive means the light transmittance of 95% or more (e.g., Al or Ru or compound thereof).

Examples of materials useful as etch stop layer 12 include materials that are resistant to etching by materials used to etch the material of the phase shift layer 15 described below. In embodiments where the phase shift layer 15 is formed of a MoSi compound, fluorine containing etchants are used to etch phase shift layer 15. In accordance with embodiments of the present disclosure, the material of the etch stop layer 12 is resistant to etching by fluorine containing etchants. Examples of fluorine containing etchants useful in the removal of portions of phase shift layer 15 include fluorine containing gases such as CF₄, CHF₃, C₂F₆, CH₂F₂, SF₆ or combinations thereof. Materials that are resistant to etching by fluorine-containing etchants and that are useful as an etch stop layer 12 include CrON, Al and an Al alloy, Ru and composites of Ru such as Ru—Nb, Ru—Zr, Ru—Ti, Ru—Y, Ru—B, Ru—P, and the like. In other embodiments, the etch stop layer 12 is light transmissive (e.g., more than about 95%) and is selected from a material having a chemical formula AlₓSi_{y}O_{z} where x+y+z=1. Embodiments in accordance with the present disclosure are not limited to etch stop layers of these specific materials. Other materials that are semi-transmissive to the incident light and are resistant to etching by fluorine containing etchants described above can be used as an etch stop layer in accordance with embodiments described herein. In other embodiments, materials that are semi-transmissive to the incident light and resistant to etching by etchants other than fluorine containing etchants that may be used to etch phase shift layer 15 can be utilized.

In some embodiments, the etch stop layer 12 can be etched with chlorine containing etchants. An advantage of utilizing an etch stop layer 12 that can be etched with chlorine containing etchants is that materials used as substrate 10, such as quartz, are not etched by chlorine containing etchants. Examples of chlorine containing etchants include a chlorine-containing gas (such as Cl₂, SiCl₄, HCl, CCl₄, CHCl₃, other chlorine-containing gas, or combinations thereof) and an oxygen-containing gas (such as O₂, other oxygen-containing gas, or combinations thereof).

In some embodiments, the etch stop layer 12 has a thickness of between about 1 to about 20 nm. In other embodiments, etch stop layer 12 has a thickness between about 1 to about 10 nm. Embodiments in accordance with the present disclosure are not limited to etch stop layers having a thickness between 1 to 20 nm or between 1 to 10 nm. For example, in some embodiments, the etch stop layer 12 may be thinner than 1 nm or may be thicker than 20 nm.

The etch stop layer 12 may be formed by various methods, including physical vapor deposition (PVD) processes (for example, evaporation and DC magnetron sputtering), plating processes (for example, electroless plating or electroplating), chemical vapor deposition (CVD) processes (for example, atmospheric pressure CVD, low-pressure CVD, plasma enhanced CVD or high-density plasma CVD), ion beam deposition, spin on coating, metal-organic decomposition (MOD), other suitable methods, or combinations thereof.

In some embodiments, the phase shift material layer 15 is in direct contact with the front surface of the etch stop layer 12 on substrate 10. The phase shift material layer 15 produces a phase shift in light that is incident on and transmitted through the phase shift material layer 15. In accordance with embodiments of the present disclosure, the degree of the phase shift produced in the light that enters the phase shift material 15 and passes through the phase shift material 15 and the patterned etch stop layer 12 compared to the phase of the incident light that does not pass through the phase shift material layer 15 or the etch stop layer 12 can be adjusted by changes in the refractive index and thickness of the phase shift material layer 15 and/or the refractive index and thickness of the etch stop layer 12. In some embodiments, the refractive index and thickness of the phase shift material layer 15 and the etch stop layer 12 are chosen so that the phase shift produced in the light that enters the phase shift material layer 15 and passes through the phase shift material 15 and the patterned etch stop layer 12 is about 180 degrees. Embodiments in accordance with the present disclosure are not limited to producing a 180° phase shift. For example, in other embodiments, the desired phase shift may be greater than or less than 180°.

In some embodiments, the transmission of incident light that enters the phase shift material 15 and passes through the phase shift material 15 and the patterned etch stop layer 12 compared to the transmission of the incident light that does not pass through the phase shift material layer 15 or the etch stop layer 12 can be adjusted by changes in the absorption coefficient of the phase shift material layer 15 and/or the etch stop layer 12.

The refractive index and thickness of the phase shift material layer 15 can be adjusted alone or in combination with the refractive index and the thickness of the etch stop layer 12 in order to provide the desired phase shift. The refractive index of the phase shift material layer 15 can be adjusted by altering the composition of the material of the phase shift material layer 15. For example, the ratio of Mo to Si in MoSi compounds can be varied to adjust the refractive index of the phase shift material layer 15. Doping the phase shift material layer 15 with elements such as B, C, O, N, Al and the like will adjust the index of refraction of the phase shift material layer 15.

In accordance with embodiments of the present disclosure, the transmission of incident light by the phase shift material layer 15 can be adjusted by adjusting the incident light absorption coefficient of the phase shift material layer 15. For example, increasing the UV or DUV absorption coefficient of the phase shift material layer 15 will decrease the transmission of incident light through the phase shift material layer 15. Decreasing the absorption coefficient of the phase shift material layer 15 will increase the transmission of incident light through the phase shift material layer 15. The absorption coefficient of the phase shift material layer 15 can be adjusted by altering the composition of the material of the phase shift material layer 15. For example, the ratio of Mo to Si in MoSi compounds can be varied to adjust the absorption coefficient of the phase shift material layer 15. Doping the phase shift material layer 15 with elements such as B, C, O, N, Al, Ge, Sn, Ta and the like will adjust the absorption coefficient of the phase shift material layer 15.

In accordance with some embodiments, the thickness of the phase shift layer 15 can be altered based on the degree of phase shift desired. For example, making the phase shift layer thicker may increase or decrease the phase shift. In other examples, making the phase shift layer thinner may increase or decrease the phase shift. In some embodiments, the phase shift layer 15 has a thickness between about 30 and 100 nanometers. It is understood that embodiments in accordance with are not limited to phase shift layer 15 having a thickness between about 30 and 100 nm. In other embodiments, the phase shift layer 15 has a thickness less than 30 nm or greater than 100 nm.

Materials useful as the phase shift layer 15 include MoSi compounds and the like. For example, phase shift layer 15 includes MoSi compounds such as MoSi, MoSiCON, MoSiON, MoSiCN, MoSiCO, MoSiO, MoSiC and MoSiN. Embodiments in accordance with the present disclosure are not limited to phase shift layers utilizing the foregoing MoSi compounds. In other embodiments, phase shift layer 15 includes compounds other than MoSi compounds that are capable of shifting the phase of light incident on the phase shift layer, e.g., for example, by 180 degrees.

The phase shift layer 15 may be formed by various methods, including physical vapor deposition (PVD) processes (for example, evaporation and DC magnetron sputtering), plating processes (for example, electroless plating or electroplating), chemical vapor deposition (CVD) processes (for example, atmospheric pressure CVD, low-pressure CVD, plasma enhanced CVD or high-density plasma CVD), ion beam deposition, spin on coating, metal-organic decomposition (MOD), other suitable methods, or combinations thereof.

The hard mask layer 20 will be patterned and the pattern of hard mask layer 20 will be transferred to the phase shift layer 15. In some embodiments, the hard mask layer 20 includes a material that protects the phase shift layer 15. In some embodiments, the hard mask layer 20 includes a chromium-containing material, such as Cr, CrN, CrO, CrC, CrON, CrCN, CrOC, CrOCN, other chromium-containing material, or combinations thereof. In some alternative embodiments, the hard mask layer 20 includes a tantalum-containing material, such as Ta, TaN, TaNH, TaHF, TaHfN, TaBSi, TaB SiN, TaB, TaBN, TaSi, TaSiN, TaGe, TaGeN, TaZr, TaZrN, other tantalum-containing material, or combinations thereof which can be etched with a fluorine-containing etchant.

In some embodiments, the hard mask layer 20 has a thickness of about 3 nm to about 400 nm. In other embodiments, the thickness of the hard mask layer 20 is in a range from about 5 nm to about 100 nm. The hard mask layer 20 may be formed by various methods, including physical vapor deposition (PVD) processes (for example, evaporation and DC magnetron sputtering), plating processes (for example, electroless plating or electroplating), chemical vapor deposition (CVD) processes (for example, atmospheric pressure CVD, low-pressure CVD, plasma enhanced CVD or high-density plasma CVD), ion beam deposition, spin on coating, metal-organic decomposition (MOD), other suitable methods, or combinations thereof.

The intermediate layer 30 of the multilayer resist system includes a material that can absorb the UV light and has a sufficient etching selectivity to the hard mask layer 20 and the phase shift layer 15 (made of different materials). In some embodiments, the intermediate layer 30 includes a transition metal or an alloy or compound of transition metal. The examples of the transition metal include Mo, Ta, Pd, Ir, Ni, Sn, Ru or Au. The Mo compounds, Ta compounds or Ru compounds as explained above with respect to the etch stop layer 12, the phase shift layer 15 and the hard mask layer 20 can be used as the intermediate layer 30. In some embodiments, the intermediate layer 30 includes an organic/polymer based Si containing material or inorganic Si based material. The inorganic Si based material includes silicon nitride, silicon oxide, silicon oxynitride, SiOC, SiOCN, SiCN, SiC, SiBN, SiBC or SiBCN. In some embodiments, the intermediate layer 30 includes amorphous or polycrystalline Si, SiGe or SiC. In some embodiments, the intermediate layer 30 includes a silicon containing polymer, such as polysiloxane. A silicon amount of the polysiloxane is about 40 wt % to about 70 wt % in some embodiments. In some embodiments, the polymer-based intermediate layer 30 further includes Si or metal particles of Mo, Ta, Pd, Jr, Ni, Sn, Ru or Au. In some embodiments, the particles have a diameter in a range from 1 nm to 20 nm, or from about 2 nm to about 10 nm. In some embodiments, the intermediate layer 30 is an organic polymer containing silicon particles and/or metal particles as set forth above.

In some embodiments, a minimum thickness of the intermediate layer 30 is about 2 nm, about 5 nm or about 10 nm, and a maximum thickness of the intermediate layer 30 is about 30 nm, about 50 nm, about 100 nm, about 150 nm or about 200 nm, or any ranges therebetween. The intermediate layer 30 is formed by CVD, PVD, ALD or any other suitable film formation process.

The photo resist layer 40 is patterned as described below in more detail and the patterned photoresist is used as a mask to pattern the underlying intermediate layer 30. In some embodiments, the pattern of the photoresist layer 40 will be transferred onto the phase shift material layer 15 in subsequent processes. In some embodiments, the photoresist layer 40 may be a chemically amplified resist that employs acid catalysis. For example, the photoresist of the photoresist layer 40 may be formulated by dissolving an acid sensitive polymer in a casting solution. In some embodiments, the photoresist of the photoresist layer 40 may be a positive tone photoresist which would render the patterns subsequently formed having the same contour as the patterns on a mask (not illustrated). In some alternative embodiments, the photoresist of the photoresist layer 40 may be a negative tone photoresist which would render the patterns subsequently formed having openings corresponding to the patterns on the mask (not illustrated). The photoresist layer 40 may be formed by spin coating or other similar techniques.

Referring to FIG. 2B, an intermediate structure after patterning of the photoresist layer 40 is illustrated. The photoresist layer 40 is patterned by performing an exposure process on the photoresist layer 40. The exposure process may include a lithography technique with a mask (for instance, a photolithography process) or a mask-less lithography technique (for instance, an electron-beam (e-beam) exposure process or an ion-beam exposure process). After the exposure process, a post-exposure baking process may be performed to harden at least a portion of the photoresist layer 40. Depending on the material(s) or type(s) of the photoresist layer 40, polymers of the photoresist layer may undergo different reactions (chain scission or cross-linking of polymers) upon the irradiation of the light beam and baking. Thereafter, a development process is performed to remove at least a portion of the photoresist layer 40. In some embodiments, portions of the positive resist material exposed to the light beam may undergo a chain scission reaction, resulting in the exposed portions being easily removed by a development agent as compared to other portions not exposed to the light beam. On the other hand, portions of the negative resist material exposed to the light beam may undergo a cross-linking reaction, resulting in the exposed portions being harder to remove by a development agent as compared to other portions not exposed to the light beam. In some embodiments, after development of the photoresist layer 40, portions of the underlying intermediate layer 30 are exposed.

Then, as shown in FIG. 2C, after development of the photoresist layer 40 is complete, the intermediate layer 30 is etched through the openings in the developed photoresist layer 40. The intermediate layer 30 is patterned by etching the exposed portions of the intermediate layer 30 through the openings in the developed photoresist layer 40. The etching process can include a dry etching process, a wet etching process, or combination thereof. The dry and wet etching processes have etching parameters that can be tuned, such as etchants used, etching temperature, etching solution concentration, etching pressure, source power, RF bias voltage, RF bias power, etchant flow rate, and other suitable parameters so as to be selective for the material of the intermediate layer 30 relative to other materials that will be exposed to the etchant during the etching of hard mask layer 20. In some embodiments, fluorine containing etchants are used in the removal of portions of the intermediate layer 30 made of, for example, an oxide or a Si based material. Examples of fluorine containing etchants include fluorine containing gases such as CF₄, CHF₃, C₂F₆, CH₂F₂, CH₃F or combinations thereof. In some embodiments, chlorine containing etchants are used in the removal of portions of the intermediate layer 30 made of, for example, a nitride based material. Examples of chlorine containing etchants include chlorine containing gases such as Cl₂, BCl₃ or combinations thereof. In some embodiments, one or more additional gases, such as O₂, Ar, N₂ or H₂, are added to the etchant gas. After the etching of the intermediate layer 30, the photoresist layer 40 is removed, as shown in FIG. 2C.

Next, as shown in FIG. 2D, the hard mask layer 20 is etched through the openings in the patterned intermediate layer 30. The hard mask layer 20 is patterned by etching the exposed portions of the hard mask layer 20 through the openings in the patterned intermediate layer 30. The etching process can include a dry etching process, a wet etching process, or combination thereof. The dry and wet etching processes have etching parameters that can be tuned, such as etchants used, etching temperature, etching solution concentration, etching pressure, source power, RF bias voltage, RF bias power, etchant flow rate, and other suitable parameters so as to be selective for the material of the hard mask layer 20 relative to other materials that will be exposed to the etchant during the etching of hard mask layer 20. In some embodiments, fluorine containing etchants are used in the removal of portions of hard mask layer 20. Examples of fluorine containing etchants include fluorine containing gases such as CF₄, CHF₃, C₂F₆, CH₂F₂, CH₃F or combinations thereof. In some embodiments, chlorine containing etchants are used in the removal of portions of the hard mask layer 20 made of, for example, a Cr based material. Examples of chlorine containing etchants include chlorine containing gases such as Cl₂, CCl₄, BCl₃ or combinations thereof. In some embodiments, one or more additional gases, such as O₂, Ar, N₂ or H₂, are added to the etchant gas. After the etching of the hard mask layer 20, the intermediate layer 30 is removed by one or more dry and/or wet etching operations and/or a chemical mechanical polishing (CMP) operation, as shown in FIG. 2D.

Then, the pattern of the hard mask layer 20 is transferred to the phase shift material layer 15 by etching phase shift material layer 15 through the openings in patterned hard mask layer 20, as shown in FIG. 2E. Patterning of phase shift material layer 15 exposes portions of the etch stop layer 12 through openings in phase shift material layer 15. Etching of phase shift material layer 15 is accomplished by exposing portions of the phase shift material layer 15 exposed through openings in the patterned hard mask layer 20 to an etchant that is selective for the material of the phase shift material layer 15 relative to the material of the hard mask layer 20 and the material of the etch stop layer 12. The etching process can include a dry etching process, a wet etching process, or combination thereof. The dry and wet etching processes have etching parameters that can be tuned, such as etchants used, etching temperature, etching solution concentration, etching pressure, source power, RF bias voltage, RF bias power, etchant flow rate, and other suitable parameters so as to be selective for the material of the phase shift material layer 15 relative to other materials that will be exposed to the etchant during the etching of phase shifting material layer 15, such as the patterned hard mask layer 20 and the stopping layer 12. In some embodiments, fluorine containing etchants are used in the removal of portions of phase shift layer 15. Examples of fluorine containing etchants include fluorine containing gases such as CF₄, CHF₃, C₂F₆, CH₂F₂, SF₆ or combinations thereof. In some embodiments, chlorine containing etchants are used in the removal of portions of the phase shift layer 15. Examples of chlorine containing etchants include chlorine containing gases such as Cl₂, CCl₄, BCl₃ or combinations thereof. In some embodiments, one or more additional gases, such as O₂, Ar, N₂ or H₂, are added to the etchant gas. After transfer of the pattern of the hard mask layer 20 to the phase shift material layer 15 is complete, the patterned hard mask layer 20 is removed to obtain the mask structure consistent with FIG. 1C.

In some embodiments, without removing the hard mask layer 20, the pattern of the hard mask layer 20 and the phase shift material layer 15 is transferred to etch stop layer 12 as shown in FIG. 2F. In some embodiments, when the etch stop layer 12 has a lower light transmittance smaller than about 95%, the etching of the etch stop layer is performed.

The transfer of the pattern of the hard mask layer 20 and the phase shift material layer 15 is achieved by etching of etch stop layer 12 through openings in the hard mask layer 20 and the phase shift material layer 15. In some embodiments, the etching of etch stop layer 12 uses a chlorine-containing gas (such as Cl₂, SiCl₄, HCl, CCl₄, CHCl₃, other chlorine-containing gas, or combinations thereof) and an oxygen-containing gas (such as O₂, other oxygen-containing gas, or combinations thereof). In other embodiments, etch stop layer 12 can be etched using an etchant other than a chlorine-containing gas and an oxygen-containing gas. For example, etch stop layer 12 can be etched using an etchant that is selective for material of etch stop layer 12 relative to the material of the hard mask layer 20 and the phase shift material layer 15 and selective for the material of etch stop layer 12 relative to the material of the substrate 10. In accordance with some embodiments, when the hard mask layer 20 and etch stop layer 12 have a similar selectivity with respect to the etchants, the patterned hard mask layer 20 can be removed in the same step that etch stop layer 12 is patterned. For example, when patterning the etch stop layer 12 utilizing a chlorine-containing etchant, the patterned hard mask layer 250 can be removed by exposure to the chlorine-containing etchant.

As shown FIG. 2F, openings are formed in the etch stop layer 12, through which portions of substrate 10 are exposed. In accordance with embodiments of the present disclosure, etching of the substrate 10 does not occur during the etching of the etch stop layer 12. After the etching of the etch stop layer 12, the hard mask layer 20 is removed, as shown in FIG. 2G. As set forth above, the hard mask layer 20 is completely removed when patterning the etch stop layer, or is removed separately from the etching of the etch stop layer 12.

In some embodiments, as shown in FIG. 2H, after the etch stop layer is etched, the substrate 10 is etched without etching or removing portions of the patterned etch stop layer 12 or the patterned phase shift material layer 15. In accordance with such embodiments, the etching of the substrate 10 removes portions of substrate 10 forming trenches or recesses as shown in FIG. 2H. The substrate 10 is etched with an etchant which does not remove the etch stop layer 12 or the phase shift material layer 15.

In some embodiment, as shown in FIG. 2I, the etch stop layer 12 is only partially removed. In some embodiments, the remaining thickness of the partially etched etch stop layer 12 is about 30% to about 80% of the unetched portion of the etch stop layer.

After etching of the etch stop layer 12 is completed, or after substrate 10 has been etched in accordance with some embodiments, the photo mask is cleaned to remove any contaminants therefrom. In some embodiments, the mask is cleaned by submerging the mask into an ammonium hydroxide (NH₄OH) solution.

In some embodiments, the hard mask layer 20 is removed from the circuit regions and not removed from the border region, thereby leaving it as the image border feature 20B (See FIGS. 1A-1D).

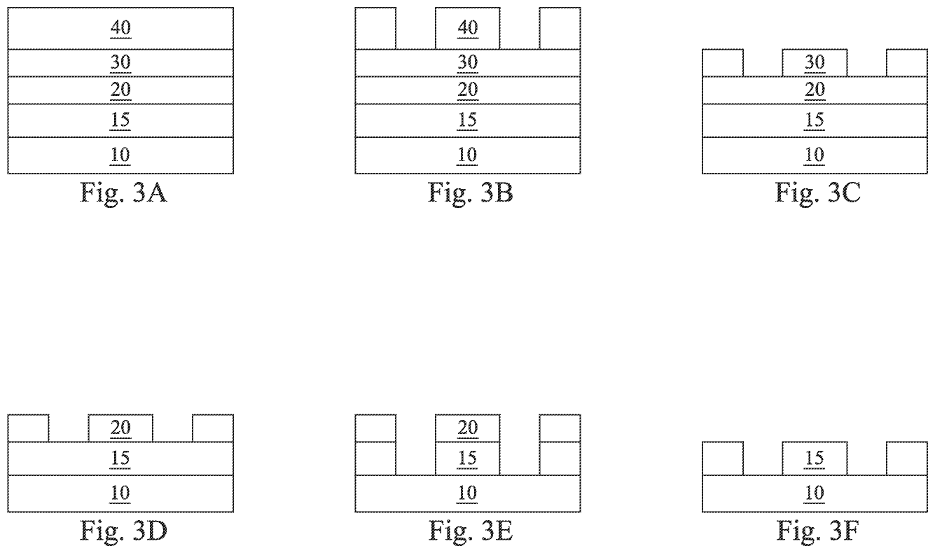

FIGS. 3A-3F schematically illustrate a sequential method of fabricating an APSM according to embodiments of the present disclosure. It is understood that additional operations can be provided before, during, and after the processes shown by FIGS. 3A-3F, and some of the operations described below can be replaced or eliminated for additional embodiments of the method. The order of the operations/processes may be interchangeable. Materials, processes, configurations and/or dimensions as explained above may be applied to the following embodiments, and the detailed explanation may be omitted.

In some embodiments, as shown in FIG. 3A, the mask blank does not include an etch stop layer between the substrate 10 and the phase shift layer 15. As shown in FIG. 3A, a multilayer resist system including the intermediate layer 30 and the photo resist layer 40 is formed over the hard mask layer 20. As shown in FIG. 3B, the photo resist layer 40 is patterned using, for example, electron beam lithography. Then, as shown in FIG. 3C, the intermediate layer 30 is patterned using the photo resist pattern as an etching mask, and the photo resist layer 40 is removed. Further, the hard mask layer 20 is patterned by using the patterned intermediate layer 30 as an etching mask, and the intermediate layer 30 is removed. Next, the phase shift layer 15 is patterned using the patterned hard mask layer 20 as an etching mask, as shown in FIG. 3E. In some embodiments, the etching substantially stops at the surface of the substrate 10. Then, part of or all of the hard mask layer 20 is removed, as shown in FIG. 3F.

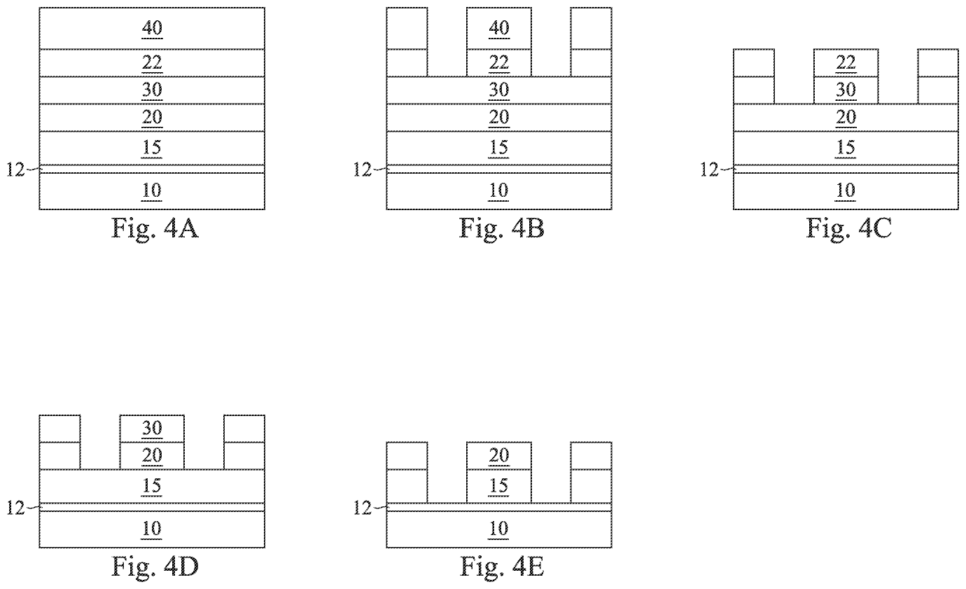

FIGS. 4A-4E schematically illustrate a sequential method of fabricating an APSM according to embodiments of the present disclosure. It is understood that additional operations can be provided before, during, and after the processes shown by FIGS. 4A-4E, and some of the operations described below can be replaced or eliminated for additional embodiments of the method. The order of the operations/processes may be interchangeable. Materials, processes, configurations and/or dimensions as explained above may be applied to the following embodiments, and the detailed explanation may be omitted.

In some embodiments, as shown in FIG. 4A, the multilayer resist system includes an intermediate layer 30, a second hard mask layer 22 and a photo resist layer 40 disposed over the first hard mask layer 20. The material and configurations of the first and second hard mask layers of FIG. 4A are the same as the hard mask layer 20 explained with respect to FIGS. 1A-1D, 2A-2H and 3A-3F. In some embodiments, at least one of the materials or configurations (e.g., thickness) of the second hard mask layer 22 is different from that of the first hard mask layer 20. In some embodiments, the material and the configuration of the first and second hard mask layers are the same.

As shown in FIG. 4B, the photo resist layer 40 is patterned using, for example, electron beam lithography, and the second hard mask layer 22 is patterned. Then, the intermediate layer 30 is patterned using the patterned second hard mask layer 22 as an etching mask, as shown in FIG. 4C. After the second hard mask layer 22 is removed, the first hard mask layer 20 is patterned by using the patterned intermediate layer 30 as an etching mask, as shown in FIG. 4D. After the intermediate layer 30 is removed, the phase shift layer 15 is patterned using the patterned hard mask layer 20 as an etching mask, as shown in FIG. 4E. Then, the operations as explained with respect to FIGS. 2E-2I are performed. In some embodiments, the etch stop layer 12 is not included similar to the embodiment of FIGS. 3A-3F, and after the phase shift layer 15 is patterned, the structure consistent with FIG. 3E is obtained.

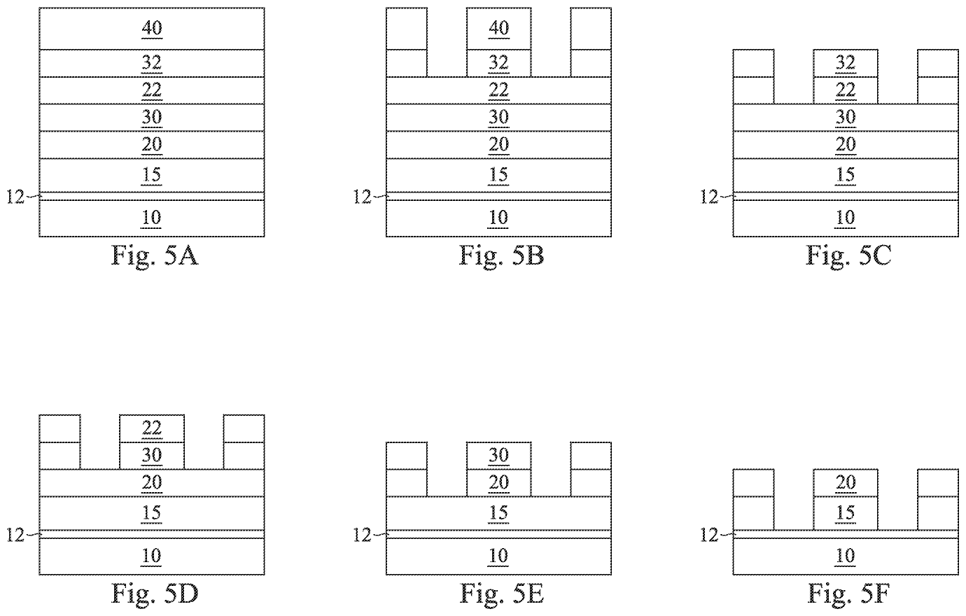

FIGS. 5A-5F schematically illustrate a sequential method of fabricating an APSM according to embodiments of the present disclosure. It is understood that additional operations can be provided before, during, and after the processes shown by FIGS. 5A-5F, and some of the operations described below can be replaced or eliminated for additional embodiments of the method. The order of the operations/processes may be interchangeable. Materials, processes, configurations and/or dimensions as explained above may be applied to the following embodiments, and the detailed explanation may be omitted.

In some embodiments, as shown in FIG. 5A, the multilayer resist system includes four layers, a first intermediate layer 30, a second hard mask layer 22, a second intermediate layer 32 and a photo resist layer 40 disposed over the first hard mask layer 20. The material and configurations of the first and second hard mask layers of FIG. 4A are the same as the hard mask layer 20 explained with respect to FIGS. 1A-1D, 2A-2H and 3A-3F, and the material and configurations of the first and second intermediate layers of FIG. 5A are the same as the intermediate layer 30 explained with respect to FIGS. 1A-1D, 2A-2H and 3A-3F. In some embodiments, at least one of the materials or configurations (e.g., thickness) of the second hard mask layer 22 is different from that of the first hard mask layer 20. In some embodiments, the material and the configuration of the first and second hard mask layers are the same. In some embodiments, at least one of the materials or configurations (e.g., thickness) of the second intermediate layer 32 is different from that of the first intermediate layer 30. In some embodiments, the material and the configuration of the first and second intermediate layers are the same.

As shown in FIG. 5B, the photo resist layer 40 is patterned using, for example, electron beam lithography, and the second intermediate layer 32 is patterned. After the photo resist layer 40 is removed, the second hard mask layer 22 is patterned using the patterned second intermediate layer 32 as an etching mask, as shown in FIG. 5C. After the second intermediate layer 32 is removed, the first intermediate layer 30 is patterned using the patterned second hard mask layer 22 as an etching mask, as shown in FIG. 5D. After the second hard mask layer 22 is removed, the first hard mask layer 20 is patterned by using the patterned first intermediate layer 30 as an etching mask, as shown in FIG. 5E. After the first intermediate layer 30 is removed, the phase shift layer 15 is patterned using the patterned hard mask layer 20 as an etching mask, as shown in FIG. 5F. Then, the operations as explained with respect to FIGS. 2E-2I are performed. In some embodiments, the etch stop layer 12 is not included similar to the embodiment of FIGS. 3A-3F, and after the phase shift layer 15 is patterned, the structure consistent with FIG. 3E is obtained.

In some embodiments, the multilayer resist system includes three or more intermediate layers and two or more hard mask layers below the photo resist layer. In some embodiments, the bottom hard mask layer in contact with the phase shift layer 15 is considered as a part of the multilayer resist system.

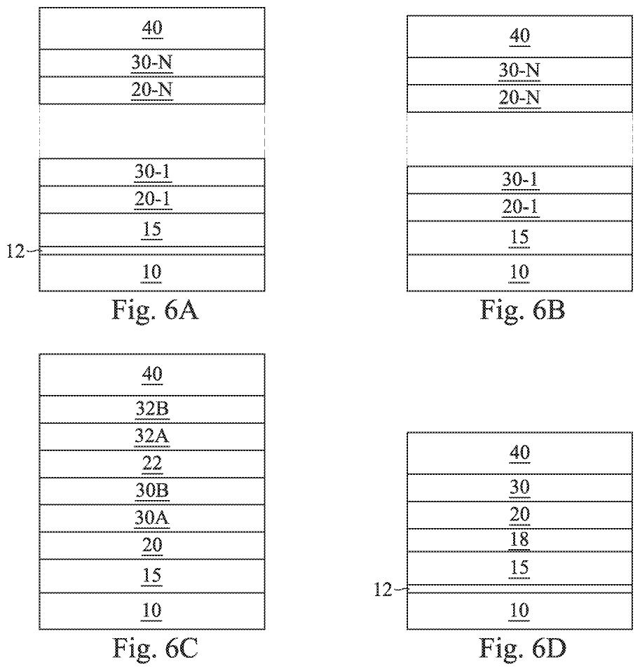

In some embodiments, as shown in FIGS. 6A and 6B, the multilayer resist system includes N-pairs of a hard mask layer and an intermediate layer on the hard mask layer, which include the first intermediate layer 30-1 to the N-th intermediate layer 30-N and the first hard mask layer 20-1 to the N-th hard mask layer 20-N, alternately stacked over the phase shift layer 15. In some embodiments, N is 2, 3, 4, or 5. In some embodiments, the uppermost one of the intermediate layer 30-N is not used and the photo resist layer 40 is disposed over the N-th hard mask layer 20-N. In FIG. 6A, an etch stop layer 12 is used, and in FIG. 6B, no etch stop layer is used.

In some embodiments, at least one of the materials or configurations (e.g., thickness) of at least one of the first to the N-th hard mask layer 22 is different from that of at least one of the remaining hard mask layers. In some embodiments, the material and the configuration of the first to N-th hard mask layers are the same. In some embodiments, at least one of the materials or configurations (e.g., thickness) of the first to N-th intermediate layers is different from that of at least one of the remaining intermediate layers. In some embodiments, the material and the configuration of the first and N-th intermediate layers are the same.

Similar to the foregoing embodiments, each of the intermediate layers and the hard mask layers are patterned step-by-step.

In some embodiments, as shown in FIG. 6C, one or more of the intermediate layers includes two or more sub-layers made of different materials from each other. In some embodiments, a bottom one of the intermediate layer includes a lower layer 30A and an upper layer 30B made of a different material then the lower layer 30A, and a upper one of the intermediate layer includes a lower layer 32A and an upper layer 32B made of a different material then the lower layer 32A. In some embodiments, the lower layer 30A is made of the same material as the lower layer 32A, and in other embodiments, the lower layer 30A is made of a different material than the lower layer 32A. Similarly, in some embodiments, the upper layer 30A is made of the same material as the upper layer 32A, and in other embodiments, the upper layer 30A is made of a different material than the upper layer 32A. Similar to the foregoing embodiments, each of the intermediate layers and the hard mask layers are patterned step-by-step. In other embodiments, the multilayer intermediate layers are etched or patterned at the same time using a patterned hard mask layer or photo resist pattern as an etching mask.

In some embodiments, as shown in FIG. 6D, an etching support layer 18 is disposed between the phase shift layer 15 and the hard mask layer 20. In some embodiments, the etching support layer 18 is patterned and utilized as an etching mask for patterning the phase shift layer 15. In some embodiments, the etching support layer 18 is made of a different material than the hard mask layer 20 and the phase shift layer 15, and includes metals, metal oxides, or other suitable materials. In some embodiments, the etching support layer 18 includes a tantalum-containing material (for example, Ta, TaN, TaNH, TaHF, TaHfN, TaB Si, TaB SiN, TaB, TaBN, TaSi, TaSiN, TaGe, TaGeN, TaZr, TaZrN, other tantalum-containing material, or combinations thereof), a chromium-containing material (for example, Cr, CrN, CrO, CrC, CrON, CrCN, CrOC, CrOCN, other chromium-containing material, or combinations thereof), a titanium-containing material (for example, Ti, TiN, other titanium-containing material, or combinations thereof), other suitable material, or combinations thereof. In some embodiments, the etching support layer 18 is made of an opaque material. Similar to the foregoing embodiments, the etching support layer 18 is patterned using the hard mask layer 20 as an etching mask, and (after the hard mask layer 20 is removed), the phase shift layer 15 is patterned using the patterned etching support layer 18. In some embodiments, the etching support layer 18 over the circuit area is removed, and part of the etching support layer remains as a border feature 20B.

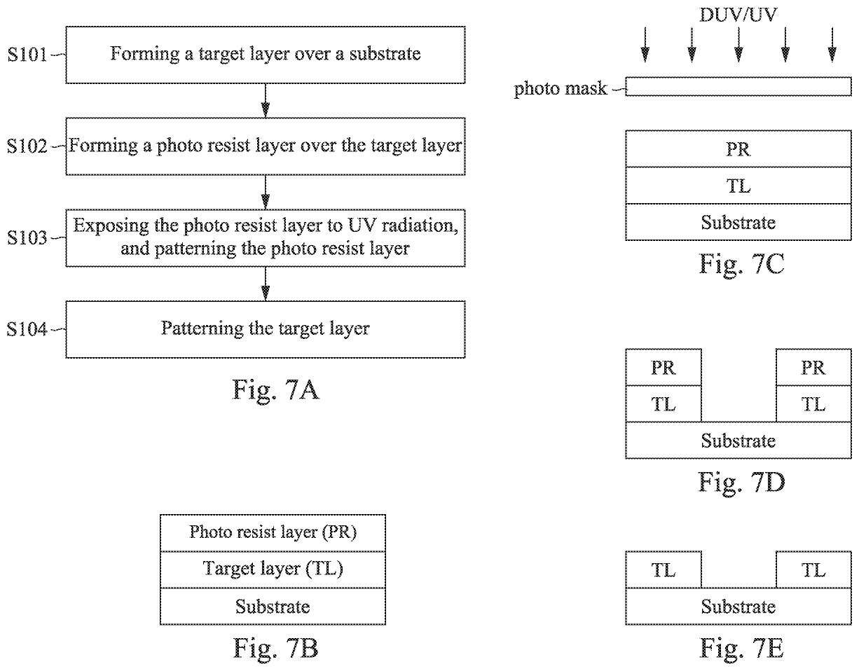

FIG. 7A shows a flowchart of a method making a semiconductor device, and FIGS. 7B, 7C, 7D and 7E show a sequential manufacturing operation of a method of making a semiconductor device in accordance with embodiments of the present disclosure.

A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S101 of FIG. 7A, a target layer to be patterned is formed over the semiconductor substrate. In certain embodiments, the target layer is the semiconductor substrate. In some embodiments, the target layer includes a conductive layer, such as a metallic layer or a polysilicon layer, a dielectric layer, such as silicon oxide, silicon nitride, SiON, SiOC, SiOCN, SiCN, hafnium oxide, or aluminum oxide, or a semiconductor layer, such as an epitaxially formed semiconductor layer. In some embodiments, the target layer is formed over an underlying structure, such as isolation structures, transistors or wirings. At S102, of FIG. 7A, a photo resist layer is formed over the target layer, as shown in FIG. 7B. The photo resist layer is sensitive to the radiation from the exposing source during a subsequent photolithography exposing process. In the present embodiment, the photo resist layer is sensitive to UV or DUV light used in the photolithography exposing process. The photo resist layer may be formed over the target layer by spin-on coating or other suitable technique. The coated photo resist layer may be further baked to drive out solvent in the photo resist layer. At S103 of FIG. 7A, the photoresist layer is patterned using one of the photo masks as set forth above, as shown in FIG. 7C. The patterning of the photoresist layer includes performing a photolithography exposing process by an DUV or UV exposing system (scanner or stepper). During the exposing process, the integrated circuit (IC) design pattern defined on the photo mask is imaged to the photoresist layer to form a latent pattern thereon. The patterning of the photoresist layer further includes developing the exposed photoresist layer to form a patterned photoresist layer having one or more openings. In one embodiment where the photoresist layer is a positive tone photoresist layer, the exposed portions of the photoresist layer are removed during the developing process. The patterning of the photoresist layer may further include other process steps, such as various baking steps at different stages. For example, a post-exposure baking (PEB) process may be implemented after the photolithography exposing process and before the developing process.

At S104 of FIG. 7A, the target layer is patterned utilizing the patterned photoresist layer as an etching mask, as shown in FIG. 7D. In some embodiments, the patterning the target layer includes applying an etching process to the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG. 7E.

In the embodiments of the present disclosure, a multilayer resist system is formed over a hard mask layer on a phase shift layer, and thus the pattern fidelity of the patterned phase shift layer can be improved. In particular, corner rounding the of the phase shift layer patterns can be suppressed.

It will be understood that not all advantages have been necessarily discussed herein, no particular advantage is required for all embodiments or examples, and other embodiments or examples may offer different advantages.

In accordance with one aspect of the present disclosure, in a method of manufacturing an attenuated phase shift mask, a photo resist pattern is formed over a mask blank. The mask blank includes a transparent substrate, an etch stop layer on the transparent substrate, a phase shift material layer on the etch stop layer, a hard mask layer on the phase shift material layer and an intermediate layer on the hard mask layer. The intermediate layer is patterned by using the photo resist pattern as an etching mask, the hard mask layer is patterned by using the patterned intermediate layer as an etching mask, and the phase shift material layer is patterned by using the patterned hard mask layer as an etching mask. The intermediate layer includes at least one selected from the group consisting of a transition metal, a transition metal alloy, or a silicon containing material, and the hard mask layer is made of a different material than the intermediate layer. In one or more of the foregoing and flowing embodiments, the intermediate layer includes at least one selected from the group consisting of Mo, Ta, Pd, Ir, Ni, Sn, Ru and Au. In one or more of the foregoing and flowing embodiments, the intermediate layer includes an alloy of at least one selected from the group consisting of Mo, Ta, Pd, Ir, Ni, Sn, Ru and Au. In one or more of the foregoing and flowing embodiments, intermediate layer includes at least one selected from the group consisting of silicon nitride, silicon oxide, silicon oxynitride, SiOC, SiOCN, SiCN, SiC, SiBN, SiBC and SiBCN. In one or more of the foregoing and flowing embodiments, intermediate layer includes a polysiloxane or an organic polymer containing Si or metal particles. In one or more of the foregoing and flowing embodiments, the hard mask layer includes at least one selected from the group consisting of Cr, CrN, CrO, CrC, CrON, CrCN, CrOC and CrOCN. In one or more of the foregoing and flowing embodiments, the etch stop layer includes at least one selected from the group consisting of Al, Ru, Ru—Nb, Ru—Zr, Ru—Ti, Ru—Y, Ru—B and Ru—P. In one or more of the foregoing and flowing embodiments, a deep ultraviolet transmittance of the etch stop layer is 95% or more. In one or more of the foregoing and flowing embodiments, a thickness of the intermediate layer is in a range from 2 nm to 200 nm. In one or more of the foregoing and flowing embodiments, the phase shift material layer is at least one selected the group consisting of MoSi, MoSiCON, MoSiON, MoSiCN, MoSiCO, MoSiO, MoSiC and MoSiN.

In accordance with another aspect of the present disclosure, in a method of manufacturing an attenuated phase shift mask, a photo resist pattern is formed over a mask blank. The mask blank includes a transparent substrate, an etch stop layer on the transparent substrate, a phase shift material layer on the etch stop layer, a first hard mask layer on the phase shift material layer, a first intermediate layer on the first hard mask layer, a second hard mask layer on the first intermediate layer, and a second intermediate layer on the second hard mask layer. The second intermediate layer is patterned by using the photo resist pattern as an etching mask, the second hard mask layer is patterned by using the patterned second intermediate layer as an etching mask, the first intermediate layer is patterned by using the patterned second hard mask layer as an etching mask, the first hard mask layer is patterned by using the patterned first intermediate layer as an etching mask, and the phase shift material layer is patterned by using the patterned first hard mask layer as an etching mask. The first and second intermediate layers include at least one selected from the group consisting of a transition metal, a transition metal alloy, or a silicon containing material, respectively, and the first and second hard mask layers are made of a different material than the first and second intermediate layers. In one or more of the foregoing and flowing embodiments, the first and second hard mask layers include at least one selected from the group consisting of Cr, CrN, CrO, CrC, CrON, CrCN, CrOC and CrOCN, respectively. In one or more of the foregoing and flowing embodiments, the first and second intermediate layers include at least one selected from the group consisting of Mo, Ta, Pd, Ir, Ni, Sn, Ru and Au and an alloy thereof, respectively. In one or more of the foregoing and flowing embodiments, first and second intermediate layers include at least one selected from the group consisting of silicon nitride, silicon oxide, silicon oxynitride, SiOC, SiOCN, SiCN, SiC, SiBN, SiBC and SiBCN, respectively. In one or more of the foregoing and flowing embodiments, the first and second intermediate layers include a polysiloxane or an organic polymer containing Si or metal particles, respectively. In one or more of the foregoing and flowing embodiments, the etch stop layer includes at least one selected from the group consisting of Al, Ru, and alloy thereof. In one or more of the foregoing and flowing embodiments, the phase shift material layer is at least one selected the group consisting of MoSi, MoSiCON, MoSiON, MoSiCN, MoSiCO, MoSiO, MoSiC and MoSiN.

In accordance with another aspect of the present disclosure, in a method of manufacturing an attenuated phase shift mask, a photo resist pattern is formed over a mask blank. The mask blank includes a transparent substrate, an etch stop layer on the transparent substrate, a phase shift material layer on the etch stop layer and a multilayer structures including N-pairs of a hard mask layer and an intermediate layer in the hard mask layer. A patterned hard mask layer is formed from a bottommost hard mask layer in the multilayer structures by patterning each of the N-pairs of the multilayer structures step-by-step, and the phase shift material layer is patterned by using the patterned hard mask layer as an etching mask. N is a natural number up to five, the intermediate layer includes at least one selected from the group consisting of a transition metal, a transition metal alloy, or a silicon containing material, respectively, and the hard mask layer is made of a different material than the intermediate layer. In one or more of the foregoing and flowing embodiments, N is 3, 4 or 5. In one or more of the foregoing and flowing embodiments, the etch stop layer is further patterned.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of manufacturing an attenuated phase shift mask, comprising:
forming a photo resist pattern over a mask blank, the mask blank including a transparent substrate, an etch stop layer on the transparent substrate, a phase shift material layer on the etch stop layer, a hard mask layer on the phase shift material layer and an intermediate layer on the hard mask layer;
patterning the intermediate layer by using the photo resist pattern as an etching mask;
patterning the hard mask layer by using the patterned intermediate layer as an etching mask; and
patterning the phase shift material layer by using the patterned hard mask layer as an etching mask, wherein:
the intermediate layer includes at least one selected from the group consisting of a transition metal, a transition metal alloy, and a silicon containing material, and
the hard mask layer is made of a different material than the intermediate layer.

2. The method of claim 1, wherein the intermediate layer includes at least one selected from the group consisting of Mo, Ta, Pd, Ir, Ni, Sn, Ru and Au.

3. The method of claim 1, wherein the intermediate layer includes an alloy of at least one selected from the group consisting of Mo, Ta, Pd, Ir, Ni, Sn, Ru and Au.

4. The method of claim 1, wherein intermediate layer includes at least one selected from the group consisting of silicon nitride, silicon oxide, silicon oxynitride, SiOC, SiOCN, SiCN, SiC, SiBN, SiBC and SiBCN.

5. The method of claim 1, wherein intermediate layer includes a polysiloxane or an organic polymer containing Si or metal particles.

6. The method of claim 1, wherein the hard mask layer includes at least one selected from the group consisting of Cr, CrN, CrO, CrC, CrON, CrCN, CrOC and CrOCN.

7. The method of claim 1, wherein the etch stop layer includes at least one selected from the group consisting of Al, Ru, Ru—Nb, Ru—Zr, Ru—Ti, Ru—Y, Ru—B and Ru—P.

8. The method of claim 1, wherein a deep ultraviolet transmittance of the etch stop layer is 95% or more.

9. The method of claim 1, wherein a thickness of the intermediate layer is in a range from 2 nm to 200 nm.

10. The method of claim 1, wherein the phase shift material layer is at least one selected from the group consisting of MoSi, MoSiCON, MoSiON, MoSiCN, MoSiCO, MoSiO, MoSiC and MoSiN.

11. A method of manufacturing an attenuated phase shift mask, comprising:
forming a photo resist pattern over a mask blank, the mask blank including a transparent substrate, an etch stop layer on the transparent substrate, a phase shift material layer on the etch stop layer, a first hard mask layer on the phase shift material layer, a first intermediate layer on the first hard mask layer, a second hard mask layer on the first intermediate layer, and a second intermediate layer on the second hard mask layer;
patterning the second intermediate layer by using the photo resist pattern as an etching mask;
patterning the second hard mask layer by using the patterned second intermediate layer as an etching mask;
patterning the first intermediate layer by using the patterned second hard mask layer as an etching mask;
patterning the first hard mask layer by using the patterned first intermediate layer as an etching mask; and
patterning the phase shift material layer by using the patterned first hard mask layer as an etching mask, wherein:
the first and second intermediate layers include at least one selected from the group consisting of a transition metal, a transition metal alloy, and a silicon containing material, respectively, and
the first and second hard mask layers are made of a different material than the first and second intermediate layers.

12. The method of claim 11, wherein the first and second hard mask layers include at least one selected from the group consisting of Cr, CrN, CrO, CrC, CrON, CrCN, CrOC and CrOCN, respectively.

13. The method of claim 12, wherein the first and second intermediate layers include at least one selected from the group consisting of Mo, Ta, Pd, Ir, Ni, Sn, Ru and Au and an alloy thereof, respectively.

14. The method of claim 12, wherein the first and second intermediate layers include at least one selected from the group consisting of silicon nitride, silicon oxide, silicon oxynitride, SiOC, SiOCN, SiCN, SiC, SiBN, SiBC and SiBCN, respectively.

15. The method of claim 12, wherein first and second intermediate layers include a polysiloxane or an organic polymer containing Si or metal particles, respectively.

16. The method of claim 12, wherein the etch stop layer includes at least one selected from the group consisting of Al, Ru, and alloy thereof.

17. The method of claim 12, wherein the phase shift material layer is at least one selected from the group consisting of MoSi, MoSiCON, MoSiON, MoSiCN, MoSiCO, MoSiO, MoSiC and MoSiN.

18. A method of manufacturing an attenuated phase shift mask, comprising:
forming a photo resist pattern over a mask blank, the mask blank including a transparent substrate, an etch stop layer on the transparent substrate, a phase shift material layer on the etch stop layer and a multilayer structures including N-pairs of a hard mask layer and an intermediate layer on the hard mask layer;
forming a patterned hard mask layer from a bottommost hard mask layer in the multilayer structures by patterning each of the N-pairs of the multilayer structures step-by-step; and
patterning the phase shift material layer by using the patterned hard mask layer as an etching mask, wherein:
N is a natural number up to five,
the intermediate layer includes at least one selected from the group consisting of a transition metal, a transition metal alloy, and a silicon containing material, and
the hard mask layer is made of a different material than the intermediate layer.

19. The method of claim 18, wherein N is 3, 4 or 5.

20. The method of claim 18, further comprising patterning the etch stop layer.
